(19) United States
(12) Patent Application Publication
(10) Pub. No.: US 2021/0335968 A1
(43) Pub. Date: Oct. 28, 2021

(54) DISPLAY PANEL AND METHOD OF MANUFACTURING SAME

(71) Applicant: SHENZHEN CHINA STAR OPTOELECTRONICS SEMICONDUCTOR DISPLAY TECHNOLOGY CO., LTD., Shenzhen (CN)

(72) Inventors: Zhenguo LIN, Shenzhen (CN); Xingyu ZHOU, Shenzhen (CN); Yuanjun HSU, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/627,377

(22) PCT Filed: Dec. 20, 2019
(86) PCT No.: PCT/CN2019/126879

§ 371 Date: Dec. 30, 2019

(30) Foreign Application Priority Data
Dec. 10, 2019 (CN) 201911257825.0

(51) Int. Cl. H01L 27/32; G02F 1/1368; H01L 51/52; G02F 1/1362

(52) U.S. Cl. CPC H01L 27/3272; G02F 1/1368; H01L 51/5234; H01L 2251/308; G02F 1/136209; H01L 2227/323; H01L 27/3265

(57) ABSTRACT

A display panel is provided. The display panel includes thin film transistors arranged in an array. A source and a drain of each of the thin film transistors each include an electrode layer, and the electrode layer of the source or the drain extends to a pixel opening area and can be used as a pixel electrode.

### FIELD OF INVENTION

The present disclosure relates to the field of display technologies, and more particularly to a display panel and a method of manufacturing the same.

### BACKGROUND OF INVENTION

Organic light emitting diode (OLED) displays are gradually becoming the mainstream of the display industry due to their advantages such as wide viewing angles, high color gamut, and low power consumption.

Currently, thin film transistors (TFTs) prepared with a metal oxide semiconductor as a channel layer have been widely used in organic light emitting diode (OLED) display panels. Top-gate TFTs have become the industry's first choice due to their small parasitic capacitance. However, there are many photomask manufacturing processes required to prepare a top-gate TFT array substrate. The current technology requires 8 or more photomasks, and the cost is high.

In summary, in a manufacturing process of the OLED display panel in the prior art, a number of photomasks is large, which is not conducive to saving production costs. It is necessary to improve a manufacturing process and a film structure to reduce the number of photomasks.

### SUMMARY OF INVENTION

The present invention provides a display panel in which a transparent metal layer and a source/drain metal layer are stacked, thereby reducing a dielectric layer for setting a pixel electrode. This can solve technical problems that a number of photomasks in a manufacturing process of a display panel in the prior art is large, which is not conducive to saving production costs.

An embodiment of the present invention provides a display panel, comprising a substrate and thin film transistors arrayed on the substrate. A source and/or a drain of each of the thin film transistors comprises a first electrode layer and a second metal layer. The first electrode layer is a transparent electrode layer, and an electrode layer of the source or the drain extends to a pixel opening area of the display panel.

In an embodiment of the present invention, each of the thin film transistors comprises a light shielding layer, an active layer, a patterned gate insulating layer, a gate, an interlayer insulating layer, the first electrode layer, and the second metal layer, which are disposed on the substrate, the first electrode layer is disposed on a surface of the interlayer insulating layer, the second metal layer is disposed on a surface of the first electrode layer, and the source and the drain are formed after patterning stacked layers of the first electrode layer and the second metal layer.

In an embodiment of the present invention, the display panel is an organic light emitting diode (OLED) display panel, the pixel opening area corresponds to a light emitting area of the OLED display panel, and the first electrode layer of the source or the drain extends to the light emitting area to serve as an anode of an OLED device or an electrode constituting a pixel capacitor.

In an embodiment of the present invention, the light emitting area is further provided with a second electrode layer, the second electrode layer and the first electrode layer form the pixel capacitor, and the second electrode layer and the active layer are disposed on a surface of a same film layer and are made of same material as the active layer.

In an embodiment of the present invention, the display panel is a liquid crystal display (LCD) display panel, the pixel opening area corresponds to a sub-pixel area of the LCD display panel, and the first electrode layer of the source or the drain extends to the sub-pixel area to serve as a pixel electrode.

In an embodiment of the present invention, material of the first electrode layer comprises one or a combination of IZO and ITO.

In an embodiment of the present invention, material of the second metal layer comprises Cu.

According to the foregoing object of the present invention, an embodiment of the present invention provides a method of manufacturing a display panel, comprising: a step S10, providing a substrate and forming thin film transistors on the substrate, the step of forming each of the thin film transistors comprising: a step S101, forming a light shielding layer, a buffer layer, an active layer, a gate insulating layer, a gate, and an interlayer insulating layer on the substrate; a step S102, forming a first electrode layer on a surface of the interlayer insulating layer, and then forming a second metal layer on a surface of the first electrode layer; and a step S103, performing a yellow light process on a combined layer of the first electrode layer and the second metal layer to form a source and a drain, wherein electrode layers of the source and the drain are each electrically connected to an ion-doped area of the active layer through a via hole, and the electrode layer of the source or the drain extends to a pixel opening area of the display panel.

In an embodiment of the present invention, the step S101 comprises that: the active layer is provided with a channel and the ion-doped area disposed at both ends of the channel, the gate insulating layer is patterned to form a gate insulating pattern layer, the gate insulating pattern layer is aligned with the channel, and the gate is aligned with the gate insulating layer.

In an embodiment of the present invention, material of the first electrode layer comprises one or a combination of IZO and ITO, and material of the second metal layer comprises Cu.

Beneficial effects of the present application are that: compared with the prior art, in the display panel and the method of manufacturing the same provided by the present invention, the source/drain metal layer of the TFT device is set as a superimposed layer of a transparent metal layer and a non-ferrous metal layer, and the transparent metal layer is extended to light emitting area of the OLED panel or the pixel area of the LCD panel to serve as the pixel electrode, or to form the pixel capacitor with other electrodes in the OLED light-emitting area. In the case of maintaining the complete lighting system, a dielectric layer is reduced, thereby reducing a photomask for preparing a contact hole, thereby saving production costs.

### DESCRIPTION OF DRAWINGS

FIG. 1 is a schematic diagram of a film structure of a display panel provided by an embodiment of the present invention.

FIG. 2A to FIG. 2K are schematic diagrams of a manufacturing process of a display panel provided by embodiments of the present invention.

### DETAILED DESCRIPTION OF PREFERRED EMBODIMENTS

Aiming at technical problems that a number of photomasks in a display panel manufacturing process of the prior art is large, which is not conducive to saving production costs, this embodiment can solve this defect.

As shown in FIG. 1, taking an organic light emitting diode (OLED) display panel as an example, a display panel provided by an embodiment of the present invention includes an array of pixel units, and the pixel units include a control area for setting a thin film transistor (TFT) device and a light emitting area for setting an OLED device.

The control area includes a patterned light shielding layer 102 formed on a surface of a transparent substrate 101, a buffer layer 103 covering the light shielding layer 102, a semiconductor layer (active layer) formed on the buffer layer 103, a gate insulating layer 104 disposed on a surface of the semiconductor layer, a gate 106 disposed on a surface of the gate insulating layer 104, an interlayer insulating layer 107 formed on the buffer layer 103 and covering the semiconductor layer, the gate insulating layer 104 and the gate 106, a drain composite metal layer and a source composite metal layer formed on a surface of the interlayer insulating layer 107, a passivation layer 108 formed on a surface of the interlayer insulating layer 107 and covering the drain composite metal layer and the source composite metal layer, and a pixel definition layer 109 formed on a surface of the passivation layer 108.

The gate insulating layer 104 is patterned to form a gate insulating pattern layer. The gate insulating pattern layer is disposed in the control area and covers a part of the semiconductor layer.

The semiconductor layer includes a first semiconductor pattern disposed in the control area and a second semiconductor pattern disposed in the light emitting area. After the semiconductor layer is ionized, an area covered by the gate insulating pattern layer and the gate 106 of the first semiconductor pattern is not ionized to maintain semiconductor characteristics, thereby forming a channel 1053 of a TFT device. Uncovered areas at both ends of the first semiconductor pattern are ionized to form a drain doped area 1054 and a source doped area 1055. Film-free layer covering of the second semiconductor pattern is ionized to form a conductor pattern 1052.

A drain contact hole connected to the drain doped area 1054 and a source contact hole connected to the source doped area 1055 are formed on the interlayer insulating layer 107. The drain composite metal layer is connected to the drain doped area 1054 through the drain contact hole. The source composite metal layer is connected to the source doped area 1055 through the source contact hole.

The drain composite metal layer includes a first electrode layer 111 prepared on a surface of the interlayer insulating layer 107 and a second metal layer 112 laminated on the first electrode layer 111. The source composite metal layer includes a second electrode layer 113 prepared on a surface of the interlayer insulating layer 107 and a third metal layer 114 which is stacked on the second electrode layer 113. The first electrode layer 111 and the second electrode layer 113 are formed on a surface of the interlayer insulating layer 107 and in a contact hole. The second electrode layer 113 extends into the light emitting area.

The light emitting area includes a conductive pattern 1052 formed by ionization. The conductive pattern 1052 and the second electrode layer 113 located in the light emitting area form a pixel capacitor. The pixel definition layer 109 forms a pixel area 115 in the light emitting area. The pixel area 115 is prepared with a light emitting layer 116. A signal terminal of the light emitting layer 116 is connected to the second electrode layer 113 located in the light emitting area. The second electrode layer 113 serves as an anode of the light emitting layer 116. A cathode 117 is prepared at another signal terminal of the light emitting layer 116.

Material of the light shielding layer 102 comprises one or two or more alloy materials of Mo, Al, Cu, and Ti. A film thickness of the light shielding layer 102 ranges from 500 A to 2000 A.

Material of the buffer layer 103 comprises a single-layer film of SiOx or SiNx or a multilayer film of a combination of the two, and a film thickness of the buffer layer 103 ranges from 1000 A to 5000 A.

Material of the semiconductor layer comprises one of IGZO, IZTO, and IGZTO, and a thickness of the semiconductor layer ranges from 100 A to 1000 A.

Material of the gate insulating layer 104 comprises a single-layer film of SiOx or SiNx or a multilayer film of a combination of the two, and a film thickness of the gate insulating layer 104 ranges from 1000 A to 3000 A.

Material of the gate 106 comprises one or two or more alloy materials of Mo, Al, Cu, and Ti, and a film thickness of the gate 106 ranges from 2000 A to 8000 A.

Material of the interlayer insulating layer 107 comprises a single-layer film of SiOx or SiNx or a multilayer film of a combination of the two. A film thickness of the interlayer insulating layer 107 ranges from 2000 A to 10000 A.

Material of the first electrode layer 111 and material of the second electrode layer 113 include one or a combination of IZO and ITO. A film thickness of the first electrode layer 111 and a film thickness of the second electrode layer 113 each range from 300 A to 2000 A. Material of the second metal layer 112 and material of the third metal layer 114 include Cu. A film thickness of the second metal layer 112 and a film thickness of the third metal layer 114 each range from 2000 A to 8000 A.

A manufacturing process of an OLED display panel according to an embodiment of the present invention is as follows.

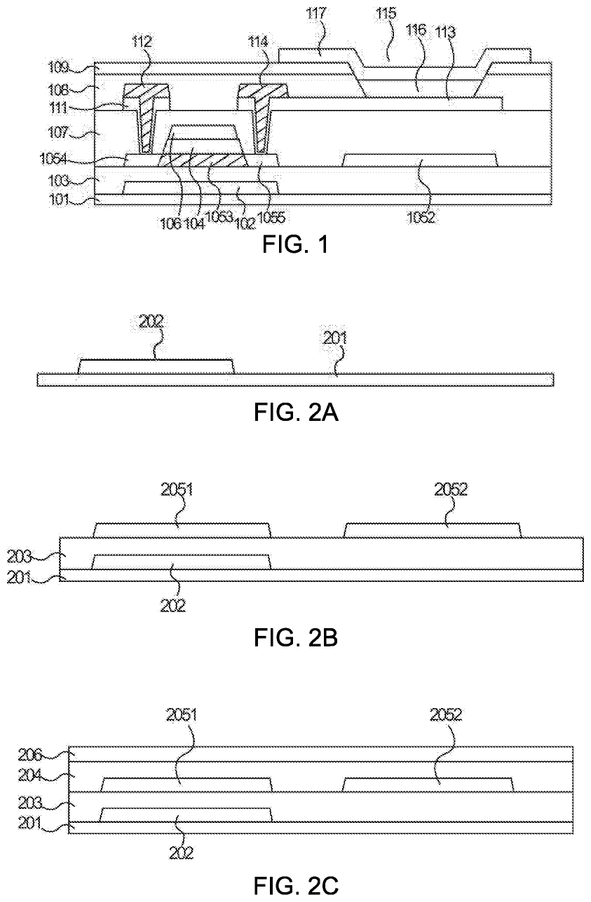

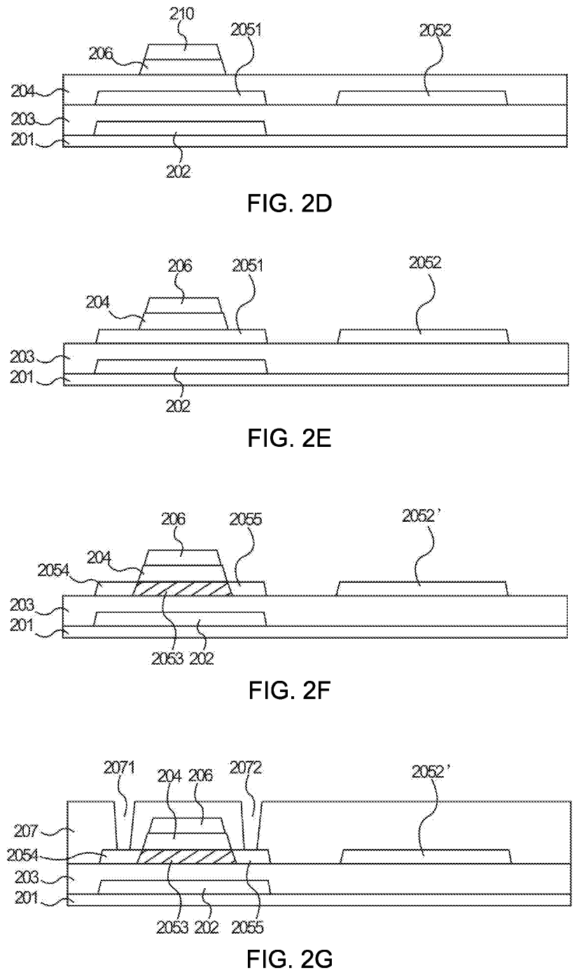

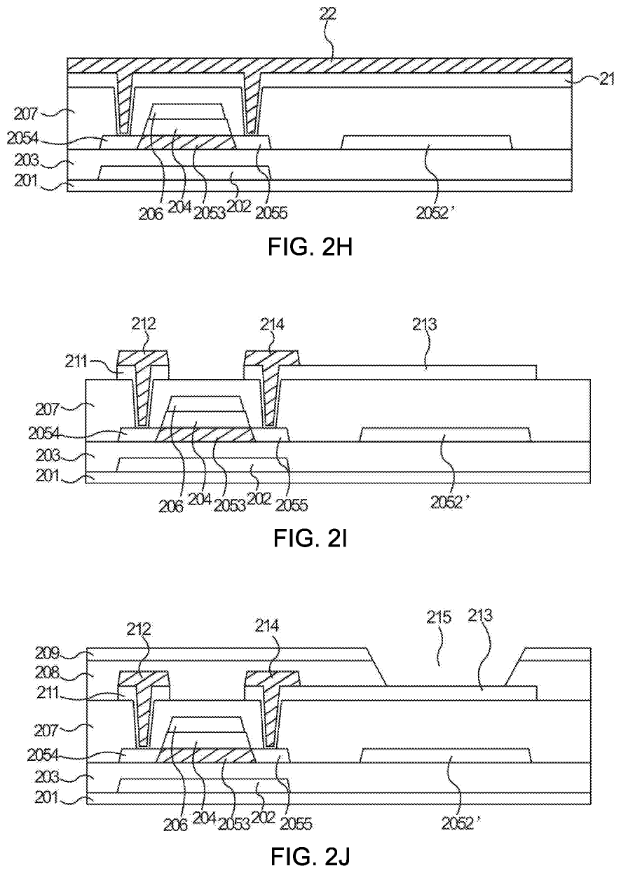

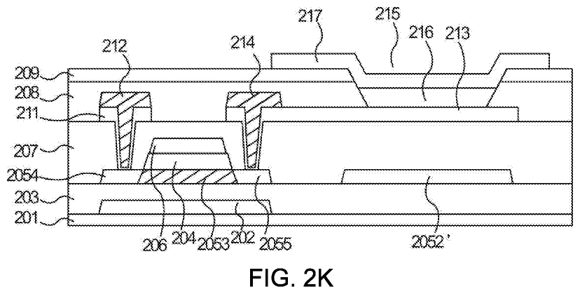

As shown in FIG. 2A, a transparent substrate 201 is provided, and a light emitting area and a control area located on one side of the light emitting area are arranged on the transparent substrate 201 in an array, and the control area is prepared with a patterned light shielding layer 202.

As shown in FIG. 2B, a buffer layer 203 covering the light shielding layer 202 and a semiconductor layer on the buffer layer 203 are prepared on the transparent substrate 201. The semiconductor layer is patterned to form a first semiconductor pattern 2051 located in the control area and a second semiconductor pattern 2052 located in the light emitting area.

As shown in FIG. 2C, a gate insulating layer 204 covering the semiconductor layer is prepared on the buffer layer 203, and a gate metal layer is prepared on the gate insulating layer 204.

As shown in FIG. 2D, a photoresist pattern 210 is provided on a surface of the gate metal layer, and FIG. 2C is processed by a yellow light process to form a gate 206.

As shown in FIG. 2E, the gate insulating layer 204 is etched to form a gate insulating pattern layer by using a gate 206 self-alignment process.

As shown in FIG. 2F, the first semiconductor pattern 2051 and the second semiconductor pattern 2052 are ionized. An area of the first semiconductor pattern 2051 covered by the gate insulating pattern layer is not ionized to maintain semiconductor characteristics, and a channel 2053 of a TFT device is formed. An exposed area of the first semiconductor pattern 2051 is ionized to form a drain doped area 2054 and a source doped area 2055. The second semiconductor pattern 2052 is ionized to form a conductor 2052′.

As shown in FIG. 2G, an interlayer insulating layer 207 is prepared on the buffer layer 203, and a first contact hole 2071 corresponding to the drain doped area 2054 and a second contact hole 2072 corresponding to the source doped area 2055 are formed on the interlayer insulating layer 207.

As shown in FIG. 2H, a transparent metal layer 21 is prepared on a surface of the interlayer insulating layer 207 and in the first contact hole 2071 and the second contact hole 2072. The transparent metal layer 21 located in the contact hole is connected to a corresponding doped area. A non-ferrous metal layer 22 is then prepared on a surface of the transparent metal layer 21.

As shown in FIG. 2I, a conventional and half-tone combined photomask is used to pattern a composite film layer of the transparent metal layer 21 and the non-ferrous metal layer 22 to form a drain composite metal pattern and a source composite metal pattern. The drain composite metal layer includes a first electrode layer 211 and a second metal layer 212. The source composite metal layer includes a second electrode layer 213 and a third metal layer 214. The second electrode layer 213 extends into the light emitting area.

As shown in FIG. 2J, a passivation layer 208 is prepared on a surface of the interlayer insulating layer 207. A pixel definition layer 209 is prepared on a surface of the passivation layer 208. The passivation layer 208 and the pixel definition layer 209 form openings in the pixel area 215 at positions of the light emitting area.

As shown in FIG. 2K, an OLED device 216 is prepared in the opening of the pixel area 215. A signal terminal of the OLED device 216 is connected to the second electrode layer 213, and another signal terminal of the OLED device 216 is prepared with a cathode 217.

Therefore, in the method of manufacturing an OLED display panel and an OLED display panel provided in embodiments of the present invention, a source/drain metal layer of a TFT device is used as an overlay layer of an electrode layer and a metal layer, and the electrode layer is extended to the light emitting area to serve as an anode of the OLED device and to form a pixel capacitor. In the case of maintaining the complete lighting system, a dielectric layer is reduced, thereby reducing a photomask for preparing a contact hole, thereby saving production costs.

Similarly, the display panel may also be an LCD display panel including an array of sub-pixel areas. The electrode layer of the source or the drain extends to the sub-pixel area and functions as a pixel electrode, which forms a potential difference with a common electrode to drive liquid crystal molecules to deflect. In the case of maintaining the complete lighting system, a dielectric layer is reduced, thereby reducing a photomask for preparing a contact hole, thereby saving production costs.

In summary, in the display panel and the method of manufacturing the same provided by embodiments of the present invention, the source/drain metal layer of the TFT device is set as an overlay layer of a transparent metal layer and a non-ferrous metal layer, and the transparent metal layer is extended to light emitting area of the OLED panel or the pixel area of the LCD panel to serve as the pixel electrode, or to form the pixel capacitor with other electrodes in the OLED light-emitting area. In the case of maintaining the complete lighting system, a dielectric layer is reduced, thereby reducing a photomask for preparing a contact hole, thereby saving production costs.

Although the present invention has been disclosed as above with preferred embodiments, the above preferred embodiments are not intended to limit the present invention. Those skilled in the art can make various modifications and retouching without departing from the spirit and scope of the present invention. Therefore, the protection scope of the present invention is subject to the scope defined by the claims.

What is claimed is:

1. A display panel, comprising:
a substrate and thin film transistors arrayed on the substrate;
wherein a source and/or a drain of each of the thin film transistors comprises a first electrode layer and a second metal layer, wherein:
the first electrode layer is a transparent electrode layer, and an electrode layer of the source or the drain extends to a pixel opening area of the display panel;
each of the thin film transistors comprises a light shielding layer, an active layer, a patterned gate insulating layer, a gate, an interlayer insulating layer, the first electrode layer, and the second metal layer, which are disposed on the substrate, the first electrode layer is disposed on a surface of the interlayer insulating layer, the second metal layer is disposed on a surface of the first electrode layer, and the source and the drain are formed after patterning stacked layers of the first electrode layer and the second metal layer.

2. The display panel according to claim 1, wherein the display panel is an organic light emitting diode (OLED) display panel, the pixel opening area corresponds to a light emitting area of the OLED display panel, and the first electrode layer of the source or the drain extends to the light emitting area to serve as an anode of an OLED device or an electrode constituting a pixel capacitor.

3. The display panel according to claim 2, wherein the light emitting area is further provided with a second electrode layer, the second electrode layer and the first electrode layer form the pixel capacitor, and the second electrode layer and the active layer are disposed on a surface of a same film layer and are made of same material as the active layer.

4. The display panel according to claim 1, wherein the display panel is a liquid crystal display (LCD) display panel, the pixel opening area corresponds to a sub-pixel area of the LCD display panel, and the first electrode layer of the source or the drain extends to the sub-pixel area to serve as a pixel electrode.

5. The display panel according to claim 1, wherein material of the first electrode layer comprises one or a combination of IZO and ITO.

6. The display panel according to claim 5, wherein material of the second metal layer comprises Cu.

7. A display panel, comprising:
a substrate and thin film transistors arrayed on the substrate;
wherein a source and/or a drain of each of the thin film transistors comprises a first electrode layer and a second metal layer, wherein:
the first electrode layer is a transparent electrode layer, and an electrode layer of the source or the drain extends to a pixel opening area of the display panel.

8. The display panel according to claim 7, wherein the display panel is an organic light emitting diode (OLED) display panel, the pixel opening area corresponds to a light emitting area of the OLED display panel, and the first electrode layer of the source or the drain extends to the light emitting area to serve as an anode of an OLED device or an electrode constituting a pixel capacitor.

9. The display panel according to claim 8, wherein the light emitting area is further provided with a second electrode layer, the second electrode layer and the first electrode layer form the pixel capacitor, and the second electrode layer and the active layer are disposed on a surface of a same film layer and are made of same material as the active layer.

10. The display panel according to claim 7, wherein the display panel is a liquid crystal display (LCD) display panel, the pixel opening area corresponds to a sub-pixel area of the LCD display panel, and the first electrode layer of the source or the drain extends to the sub-pixel area to serve as a pixel electrode.

11. The display panel according to claim 7, wherein material of the first electrode layer comprises one or a combination of IZO and ITO.

12. The display panel according to claim 11, wherein material of the second metal layer comprises Cu.

13. A method of manufacturing a display panel, comprising:
a step S10, providing a substrate and forming thin film transistors on the substrate, the step of forming each of the thin film transistors comprising:
a step S101, forming a light shielding layer, a buffer layer, an active layer, a gate insulating layer, a gate, and an interlayer insulating layer on the substrate;
a step S102, forming a first electrode layer on a surface of the interlayer insulating layer, and then forming a second metal layer on a surface of the first electrode layer; and
a step S103, performing a yellow light process on a combined layer of the first electrode layer and the second metal layer to form a source and a drain, wherein electrode layers of the source and the drain are each electrically connected to an ion-doped area of the active layer through a via hole, and the electrode layer of the source or the drain extends to a pixel opening area of the display panel.

14. The method according to claim 13, wherein the step S101 comprises that:
the active layer is provided with a channel and the ion-doped area disposed at both ends of the channel, the gate insulating layer is patterned to form a gate insulating pattern layer, the gate insulating pattern layer is aligned with the channel, and the gate is aligned with the gate insulating layer.

15. The method according to claim 13, wherein material of the first electrode layer comprises one or a combination of IZO and ITO, and material of the second metal layer comprises Cu.
